(19) United States
(12) Patent Application Publication
(10) Pub. No.: US 2025/0316489 A1
(43) Pub. Date: Oct. 9, 2025

(54) SEMICONDUCTOR DEVICE FABRICATION METHODS AND DEVICES FOR FORMING THE SAME

(71) Applicant: TAIWAN SEMICONDUCTOR MANUFACTURING COMPANY, LTD., Hsinchu (TW)

(72) Inventors: Yu-Jing CHIU, Hsinchu City (TW); Jhih Guang WU, Kaohsiung City (TW); Hui-Chi HUANG, Hsinchu County (TW); Chih Hung CHEN, Hsinchu City (TW)

(21) Appl. No.: 18/626,386

(22) Filed: Apr. 4, 2024

(51) Int. Cl. H01L 21/306; H01L 21/321; H01L 21/67

(52) U.S. Cl. CPC H01L 21/30625; H01L 21/3212; H01L 21/67092; H01L 21/67253

(57) ABSTRACT

A chemical mechanical polishing device is provided. The chemical mechanical polishing device includes a porous polishing pad in which a plurality of pores is formed and a plurality of discrete segments at one side thereof. The segments have a maximum width S_{d} no larger than a predetermined value, for example, 5 mm, to prevent from laterally spreading a deformation caused by a downward force applied thereto.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In pursuit of higher device density, higher performance, and lower costs, challenges from both fabrication and design issues have resulted in the development of three-dimensional designs, such as a multi-gate field effect transistor (FET), including a nanosheet FET. One of the challenges arising from the increased number of interconnect layers in a given IC involves a chemical-mechanical polishing (CMP) process which is often used to selectively remove high elevation features by a combination of mechanical polishing and chemical reaction.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a side view of a CMP device.

FIG. 2 shows a cross-sectional view of a polishing pad according to some embodiments.

FIG. 3 is a perspective view of a polishing pad according to some embodiments.

FIG. 4 shows the long-range pad deformation and the short-range pad deformation for polishing pads in two different configurations.

FIGS. 5-9 are top or bottom views of segments formed on pad bases of a polishing pad according to some embodiments.

FIG. 10 shows the process of fabricating a polishing pad according to some embodiments.

FIG. 11 are cross-sectional views of polishing pads with segments in various arrangements according to some embodiment.

FIG. 12 are cross-sectional views of polishing pads with segments in various arrangements according to some embodiments.

FIGS. 13-15 show a process for forming a shallow trench isolation (STI) using the CMP process for planarization.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Fabrication of complex devices involves multiple semiconductor processing steps such as lithography, etch, deposition, and CMP. CMP is an enabler for the transition from planar to 3D device integration of both logic and memory chips, each of which has multiple CMP passes. The CMP process removes and planarizes excess material on the front surface of the wafer by applying downward force across the backside of the wafer and pressing the front surface against a rotating pad of special material that contains a mixture of chemicals and abrasive materials. The CMP application includes shallow trench isolation (STI), inter-layer dielectric (ILD), tungsten interconnect, copper damascene, and other existing or new emerging applications.

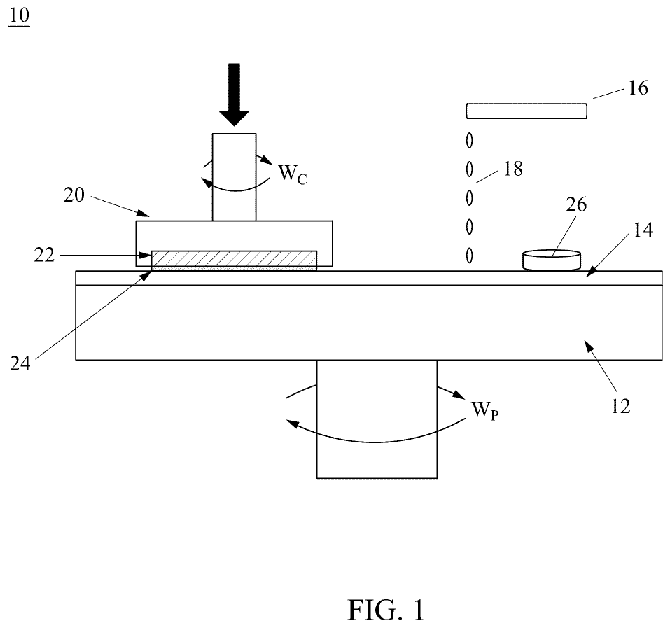

FIG. 1 shows an exemplary CMP device used in the planarization process. The CMP device 10 includes a platen 12 which may be driven to rotate with an angular speed wₚ. A polishing pad 14 is disposed on the front surface of the platen 12. A slurry supply 16 is placed above the platen 12 to supply slurry 18 on the polish pad 14 disposed on front surface of the platen 12. To polish a surface of a wafer 24, the CMP device 10 includes a wafter carrier 20 to retain the wafer 24 on a carrier film 22 within the wafer carrier 20. As shown in FIG. 1, the wafer 24 may be driven by the wafer carrier 20 to rotate with an angular speed w_{c}. The wafer carrier 20 may hold the wafer 24 with the use of vacuum during planarization to keep the wafer 24 in place and with either a removable retaining ring or a wafer guide to avoid dislodgement. In some embodiments, the CMP device 10 may include multiple wafer carriers 20 to planarize multiple wafers at the same time.

In some embodiments, the polishing pad 14 is circular and the wafer 24 is placed with its face down and forced against the polishing pad 14. The platen 12 is rotated about its own axis, and the wafer 24 is driven by rotating the wafer carrier 20 about its axis. The forces applied through the wafer carrier 20 on the wafer 24 may be adjustable within a predetermined range of, for example, 1 to 10 psi. The force applied through the wafer carrier 20 on the wafer 24 may be adjusted to suit the material being polished. To polish an oxide material, the higher end of the range is applied, while metal polishing is performed with the force in the lower end of the range. An important element of a CMP process is to have well controlled pressure applied uniformly over the wafer 24 and well controlled rotation rates of the wafer carrier 20 and the platen 12, w_{c} and wₚ respectively. The slurry 18 is dispensed from the tube-like slurry supply 16 in front of the wafer 24, so that when the platen 12 is rotated, the slurry 18 is pulled under the wafer 24. The bottom of the retaining ring of the wafer carrier 20 may be recessed from the plane of the bottom of the wafer 24 in some embodiments.

During polishing, the surface of the polishing pad 14 is in direct contact with the wafer 24. The contact surface of the polishing pad 14 provides two functions of material removals. The first function is to deliver slurry 18 to the material removal region and remove byproduct. The second function is to exert pressure on individual material regions of the wafer 24. The polishing pad 14 plays a significant role in modulating flow of the slurry 18 and has significant impact on resulting polished wafer quality. The efficiency of slurry transport by the polishing pad 14 influence material removal rate (RR), wafer polishing uniformity, wafer scratch defects, planarization efficiency, and CMP process stability. The slurry transport is facilitated by porosity, groove design, and pad surface roughness (asperity). The groove design plays an important role along with the surface roughness. Groove designs may control slurry flow, resulting in polishing rate uniformity, defect control, and effective consumption rate of the slurry 18.

The contact area between the wafer 24 and the polishing pad 14 has significant influence on the material removal rate RR and defectivity. Higher asperity-wafer contact area is desirable as it lowers stress at asperity contact points and hence lowers defectivity. The contact area depends on surface morphology, which in turns depends on pore size, pore size distribution, and material properties. Therefore, it is desirable to manufacture pads with controlled porosity and pore size to increase the pad-wafer contact area as well as to maintain pad-to-pad polishing consistency.

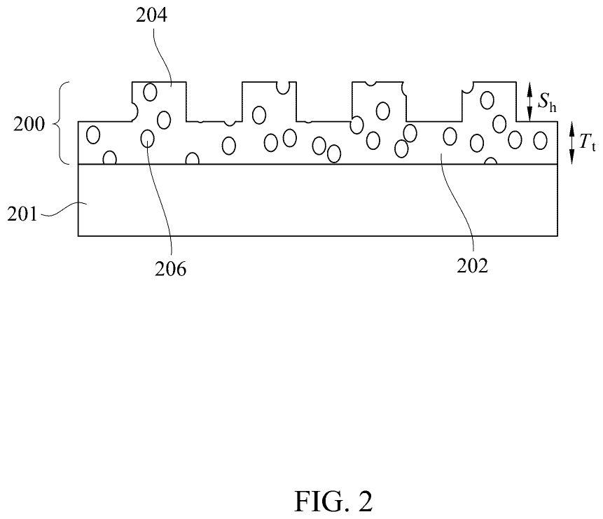

As shown in FIG. 1, the CMP device 10 may further include a conditioner 26 to revitalize the polishing pad 14 either in between wafers or in situ. While planarizing, the interaction at the interface between the polishing pad 14 and wafer 24 generating residues from material removed from the surface of the wafer, the clusters formed by agglomeration of the abrasive particles contained in the slurry 18, and the abraded polymer material of the polishing pad 14. The residues may fill the pores (see 206 in FIG. 2) to result in a smooth surface of the polishing pad 14 which degrades the planarization capability and distribution of the slurry 18. The conditioner 26 may include a diamond-coated disk and that is often referred to as a diamond dresser. The conditioner 26 determines the intrinsic asperity of the polishing pad 14, so as to maintain surface stability through the removal of worn surface material and restoration of the intrinsic structure. The conditioning process is critical as an inadequately roughened polishing pad 14 my result in a very low polishing rate. Surface topologies of the polishing pad 14 play a key role as they transmit normal force and impart tangential motion to the hard, nano-scale abrasive particles in the slurry 18.

Various types of polishing pads have been developed for dielectric CMP, polysilicon CMP, and metal CMP. For example, the polishing pad may include a pad formed by processes during fabrication of a bulk material of a polishing pad. The polishing pad is typically thicker to allow the conditioner 26 to perform diamond dressing on the surface thereof. Therefore, the pad stability can be properly maintained. However, with the continuous bulk surface structure, a long-range deformation downward force is applied towards the porous pad during the polishing process, long-range deformation may be caused by lateral spread of the force. A poor uniformity at the wafer edge is expected, particularly for a wafer with a radius larger than 140 mm. The empirical data show that the normalized thickness of a wafer that has been polished using the porous polishing pad with a continuous bulk surface structure may exceed a tolerable range such as ±20 Å, particularly at the edge of the wafer. The within wafer (WIW) and within zone (WiZ) control of the wafer edge are challenging using the porous polishing pad control with a continuous bulk surface structure. Loss of wafer edge yield and degraded chip edge electrical properties may occur consequently.

Another type of polishing pad includes a molded or printed pad. The molded pad is typically formed with a patterned top surface designed to avoid impact of wafer edge yield and chip edge electricity properties. The molded or printed pad may be formed by various processes such as injection molding or three-dimensional (3D) printing, respectively. The molded pad is typically formed thinner and without pores. As the surface design, including the groove design, can be properly controlled, the molded pads may provide better control in edge uniformity. However, there are also challenges with non-porous pads. The primary challenge is that non-porous pads require more rigorous pad break-in to achieve optimum polishing performance. For effective polishing, the pad surface must have both micro-texture, which refers to the roughness of the pad surface and the presence of asperities which contact the wafer during polishing. During pad break-in, the surface of the pad is roughened using typically the conditioner 26 as discussed above. With porous pads, the pores in the pad surface inherently create a surface which is initially rougher than the surface of a non-porous pad, so conditioning is effectively given a head start. In contrast, with non-porous pads, the initial surface is much smoother and all the micro-texture must be created by the conditioning process. Thus, non-porous pads require a longer conditioning break-in cycle and the removal rate decay, observed when abrasive conditioning is stopped during polishing, is higher.

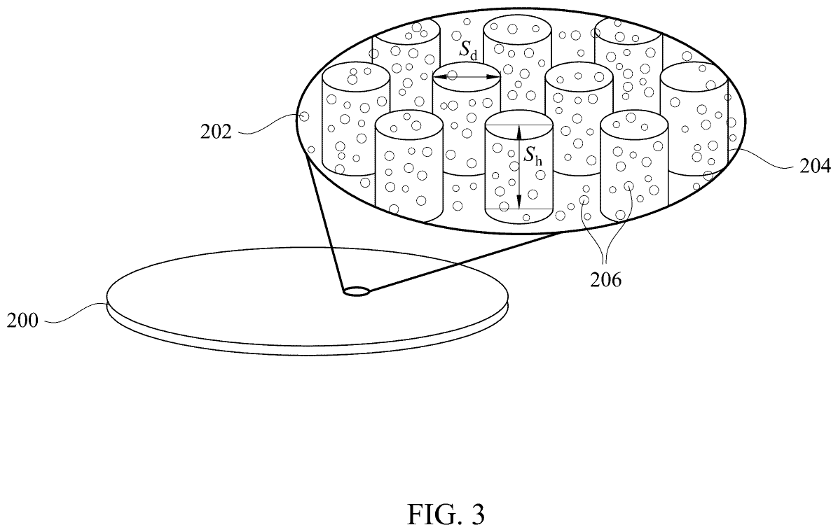

To minimize pad deformation and improve edge uniformity of the polished wafer without trading off the pad stability, segment structure is introduced to a porous pad according to some embodiments. FIG. 2 is a cross-sectional view of a polishing pad provided according to some embodiments. FIG. 3 is a perspective view of the polishing pad and an enlarged view of a portion of the polishing pad. As shown in FIG. 2, the polishing pad 200 is placed on a platen 201. Functions and operations of the polishing pad 200 and the platen 201 are similar to the polishing pad 14 and the platen 12 as described above with reference to FIG. 1. The polishing pad 200 includes a pad base 202 and a plurality of segments 204 formed on the pad base 202. According to some embodiments, the pad base 202 may be in the form of a circular disk or a disk with other suitable shapes. The thickness of the pad base 202 is denoted as Tₜ. A plurality of pores 206 are formed in the pad base 202. Each of the segments 204 has a maximum width S_{d} and a height Sₕ. In the embodiment as shown in FIG. 3, each segment 204 is in the form as a cylinder and the maximum width S_{d} and the height Sₕ are the diameter of the top and bottom surface, and height of each cylindrical segment 204.

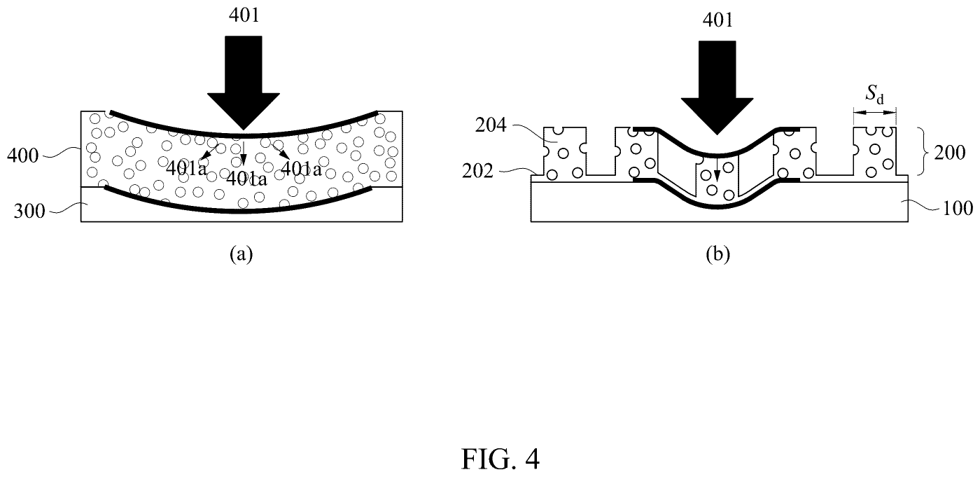

During the polishing process, a downward force is applied towards the polishing pad. The downward force may resolve into component forces spread along different directions on the polishing pad. For example, when the polishing pad 400 includes a continuous structure as shown in (a) of FIG. 4, the downward force 401 applied on the polishing pad 400 may resolve into several component forces 401a along different directions. The several component forces push the area surrounding the stress point of the polishing pad along directions inclined away from the vertical direction to cause a long-range pad deformation of the polishing pad. As the controlled zone within the wafer becomes smaller and smaller, the undesired deformation of the surrounding zones may cause the polishing instability of the wafer. In contrast, when the downward force 401 is applied to the polishing pad 200 with a plurality of discrete segments 204 formed on the pad base 202 as shown in (b) of FIG. 4, the segments 204 around the stress point will not deform as the lateral force may not spread thereto through the gaps between the segments. As a result, the deformation caused by the downward force may be restricted substantially downward within the small zone at the stress point. As the deformation is controlled in short range or a local zone, a better zone-to-zone control can be achieved by the formation of discrete segments 204.

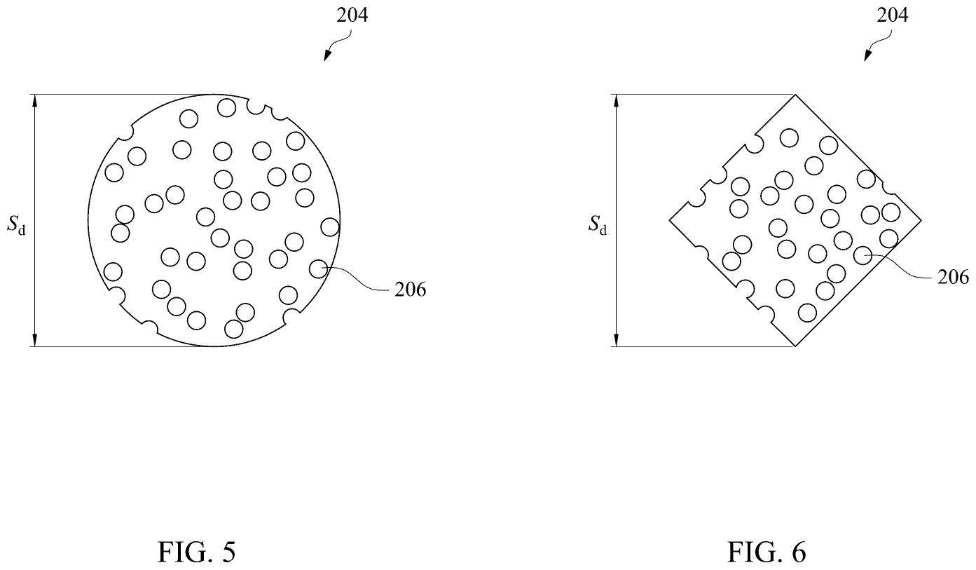

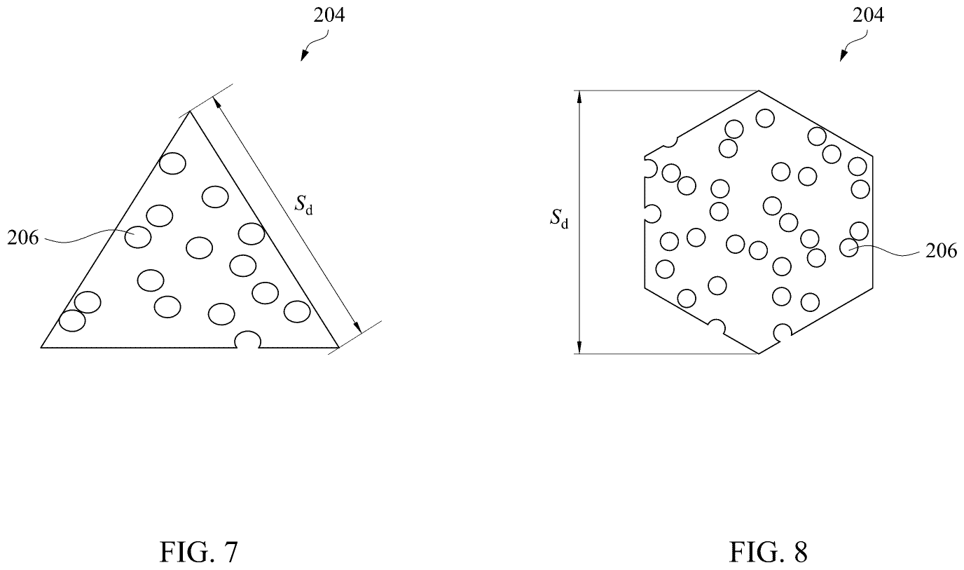

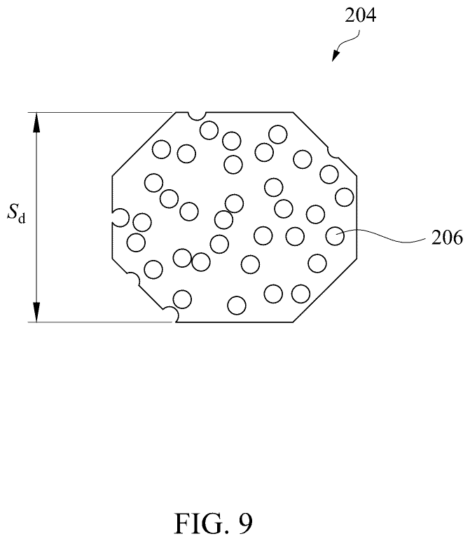

In addition to the cylindrical shape as shown in FIGS. 3 and 5, the segments may be formed with other geometric structures. FIGS. 6-9 are top views of various geometric shapes of the segments 204 according to some in embodiments. In FIG. 6, the segments 204 are in the forms of tetragonal prisms or tetragonal columns with square, rectangular, or other tetragonal top and bottom faces such as trapezoid, parallelgram. The maximum width S_{d} of the tetragonal prism is the longest diagonal length of the tetragonal top and bottom faces. FIG. 7 shows the top (bottom) face of a triangular prism or triangular column. The maximum width S_{d} of the triangular column is the longest side of the top face and the bottom face. In some embodiments, the maximum length S_{d} of each segment 204 is smaller than 5 mm to avoid the long-range deformation caused by the downward force 401 applied thereto during the polishing process. FIG. 8 is a top (bottom) view of a segment 204 in the form of a hexagonal prism. The maximum width S_{d} is the distance between any pair of opposing corners of the top or bottom face of the hexagonal prism. When the segments are in the forms of octagonal prisms, the maximum width S_{d} is the shortest distance between each pair of parallel sides of the top or bottom face as shown in the segment 204 in FIG. 9. Similarly, to minimize the long-range pad deformation (see FIG. 4(a)) caused by the downward force during polishing, the maximum width S_{d} may be controlled smaller than about 5 mm.

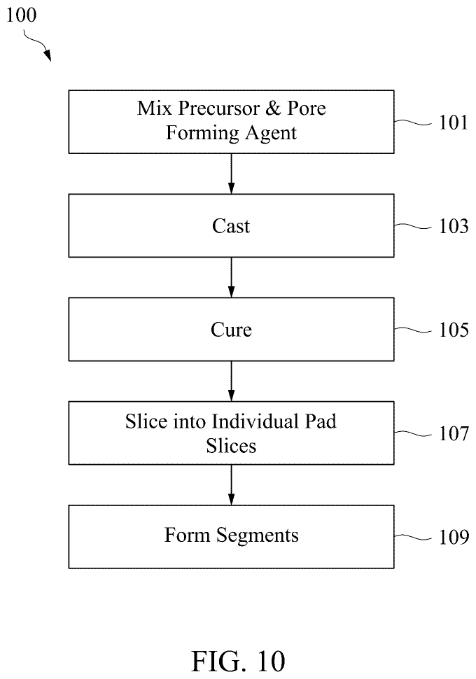

Various methods may be used to fabricate polishing pads capable of polishing materials and structures such as silicon (Si), interlayer dielectric (ILD), shallow trench isolation (STI), metal, and other materials. FIG. 10 shows the process of forming a polishing pad according to one embodiment. At block 101, a precursor of the pad material is mixed with pore foaming agent. Since chemical-mechanical planarization is both a chemical process and a mechanical process, the polishing pad must have sufficient mechanical integrity and chemical resistance to survive the rigors of polishing. The pad material may be selected from the polymeric materials with high strength to resist tearing during polishing. Acceptable levels of hardness and modulus are selected based on the material to be polished, and good abrasion resistance is desired to prevent excessive pad wear during polishing. Chemically, the pad material must be able to survive the aggressive slurry chemistries in the CMP polishing without degrading, delaminating, blistering, or warping. In addition, the polishing pad must be sufficiently hydrophilic to avoid wetting the surface and to allow water to be easily swept away from the surface of the wafer. The hydrophilic level may be presented by Critical Surface Tension. Suitable Critical Surface Tension may range from about 37 mN/m to about 45 mN/m or higher according to some embodiments. Another criterion for selecting the pad material includes the polymer formulation and morphology being variable to provide specific, predictable properties for different polishing applications. Among various polymeric materials, polyurethane appears to be the material that best satisfies the above criteria for forming the polishing pad. Other materials such as polyimide, polyester, polycarbonate, poly(methyl methacrylate), nylons, polysulfones, or other similar polymeric materials may also be used for forming the polishing pad.

Depending on the specific application, hardness of the polishing pad may vary from about 10 Shore D to about 80 Shore D. In general, harder pads may be used for planarization of oxide dielectric layers, shallow trench isolation, and tungsten plugs and conductors. Slightly softer pads are used for polishing copper damascene features, and still softer pads are used in final buff polishing to remove defects from the earlier steps. When polyurethane or other similar polymeric material is selected for forming the polishing pad, it is possible to vary hardness from Shore D values between the range of about 15 and about 65.

At block 103, the mixture is cast at an elevated temperature. In some embodiments, the mixture may be cast into a mold for a predetermined period of time. At block 105, the mixture is cured at a further elevated temperature. The cured mixture is then cooled down and sliced into individual polishing pads at block 107. At block 109, cutting or machining is performed from one side of a polishing pad to form discrete segments. As discussed above, each of the segments may have a maximum width S_{d} smaller than 5 mm to minimize the long-range pad deformation during polishing. The segments may be formed with different geometric shapes such as those shown in FIGS. 5-9.

Porosity or foam structure of the polishing pad aids the chemical action in the CMP process by transporting slurry to all parts of the wafer uniformly. Regarding the mechanical action in the CMP process, the pores facilitate transportation of the removed material from the wafer surface. Without a sufficiently porous structure, the free flow of slurry in and out of the pad would be impeded to result in decrease of material removal from the wafer surface. In addition, the material removal rate RR of a wafer is inversely proportional to the pad density and compressibility. Pad density and compressibility have a strong relationship with the pore size and number of pores. If a polishing pad has a large pore size, the pad density may be low and the compressibility may be high. The low pad density results in low elastic and shear modulus, causing large deformation and higher compressibility of the polishing pad. According to some embodiments, the pore may have a size, that is, a diameter, ranging from about 5 nm to about 50 nm to ensure an appropriate material removal rate RR of the wafer being polished.

The formation of discrete segments creates grooves between adjacent segments. Arrangement of the grooves, that is, a groove design may change across the polishing pad based on the design of the segments. Grooves formed at the contact surface between the polishing pad and the wafer to be polished may prevent hydroplaning of the wafer. The polishing pad without grooves may result in a continuous layer of polishing fluid existing between the polishing pad and the wafer, thus preventing uniform intimate contact and significantly reduces removal rate RR. Grooves also help slurry uniformly distributed across the polishing pad and allow sufficient slurry to reach the interior of the wafer for polishing. This is particularly important when polishing reactive metal such as copper in which the chemical component is as critical as the mechanical component of polishing. Uniform slurry distribution across the polishing pad is desired to achieve the same polishing rate at the center and the edge of wafer. The design of segments and grooves may control both overall and localized stiffness of the polishing pad; and further controls the polishing uniformity across the wafer and the ability of the polishing pad to level features of different heights to give a highly planar surface of the wafer after being polished. Different regions of the polishing pads may have different segment and groove designs. Debris built up may increase the likelihood of scratches and defects. The grooves may also act as channels for removal of polishing debris from the pad surface since new slurry replaces the old one, and the old slurry being replaced may carry the entrained debris with it and thus remove the debris.

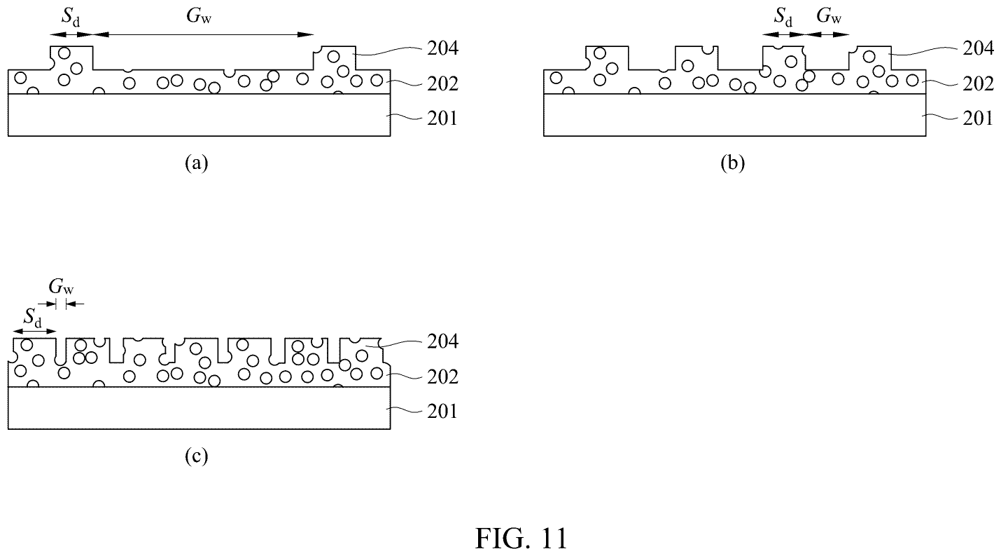

The segments may be formed with different heights Sₕ and maximum widths S_{d}. The maximum width S_{d} and the arrangement of the segments, for example, the number of segments arranged on a specific surface area determines the groove width G_{w}. Both the groove width G_{w} and the segment height Sn are factors that determine lifetime of the polishing pad. In some embodiments, the designs of the segments and grooves depend on the material to be polished. The designs of the segments and grooves may also depend on the polishing effect as desired. For example, the user may select a groove design with specific groove width G_{w} and maximum width of the segment S_{d} to achieve the desired material removal rate RR. According to some embodiments, the maximum width S_{d} may vary from about 0.5 mm to about 5 mm, and the groove width G_{w} may range from about 0.2 mm to about 5 mm. The S_{d}/G_{w} ratio may vary from about 0.2 to about 5. When the S_{d}/G_{w} ratio is lower than 0.2, the polishing pad includes insufficient amount of segments, such that the issues caused by lateral deformation may not be resolved. In contrast, a S_{d}/G_{w} ratio larger than 5 may cause significant impact in removal efficiency of the polishing process. FIGS. 11(a) to 11(c) are cross-sectional views of polishing pads 200 with different number of segments 204 arranged within the same surface area of the pad base 202 placed on a platen 201. In FIG. 11(a), two segments 204 with a maximum width S_{d} arranged within the surface area of the pad base 202 defines a first groove width G_{w1}. The S_{b}/G_{w} ratio is as low as about 0.2. The groove between the adjacent segments 204 provides a space to retain and distribute a first amount the slurry during polishing to result in a material removal rate RRa. In FIG. 11(b), four segments 204 with the maximum width S_{d} arranged within the same surface area of the pad base 202 defines a second groove width G_{w2}. The groove width G_{w} is smaller than the groove width G_{w1}. The S_{d}/G_{w} ratio is about 1. The grooves between the adjacent segments 204 provide spaces to retain and distribute a second amount of the slurry during polishing and results in a second material removal rate RRb. In FIG. 11(c), seven segments 204 with maximum width S_{d} are arranged within the same surface area of the pad base 202 to define a groove width G_{w3}. The S_{d}/G_{w} is about 5. The grooves between the adjacent segments 204 provide spaces to retain and distribute a third amount of slurry during polishing to result in a third material removal rate RRc. The relationships between three groove width and the S_{d}/G_{w} ratio may be presented as:

$${G}_{w 1} > {G}_{w 2} > {G}_{w 3} , and$$

$${S}_{d} / {G}_{w 1} < {S}_{d} / {G}_{w 2} < {S}_{d} / Gw 3.$$

As a result, the relationship between the material removal rate may be presented as:

$$RRa > RRb > RRc .$$

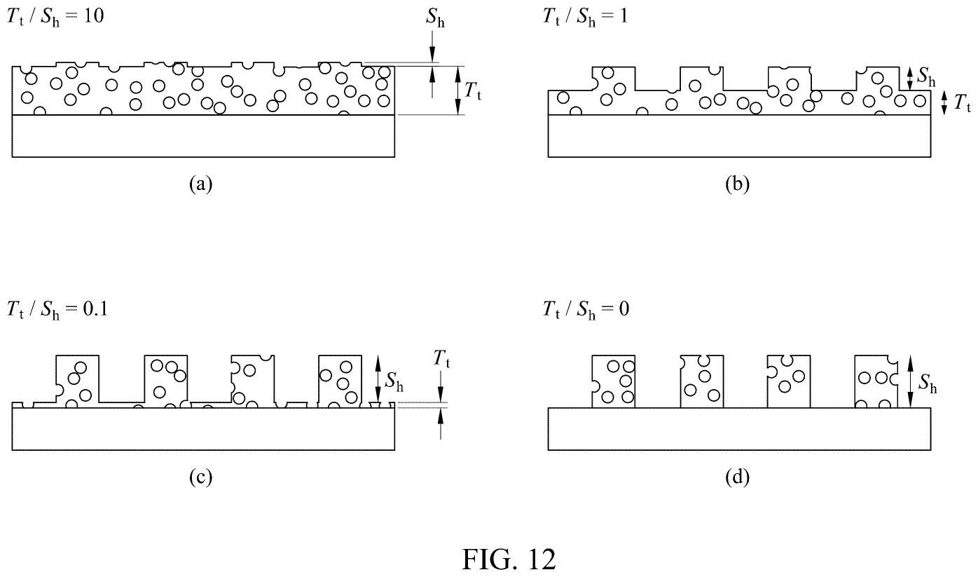

Not only the groove width affects the performance of CMP polishing process, the depth of the grooves, that is, the height of the segments also plays an important role of the CMP polishing process. The depth of grooves is one of the factors for determining the lifetime of the polishing pad since acceptable polishing performance is possible only before the polishing pad has been worn to the point where grooves have insufficient depth to distribute slurry, remove waste, and prevent hydroplaning. The segments 204 are formed by cutting away portions of the polishing pad 200 from one side thereof. The remaining portions of the polishing pad 200 may include a plurality of segments 204 and a pad base 202 under the segments 204. The removed thickness of the polishing pad reflects the height Sₕ of the segments 204, which also determines groove depth. The thickness of the pad base 202 may be denoted by Tₜ. The cross-sectional views of FIGS. 12(a) to 12(d) show the polishing pad 200 with segment heights Sₕ, which in turn reflect to different thickness Tₕ of the pad base 202. According to some embodiments, the segment height Sₕ may vary from about 0 mm to about 3 mm, and the thickness of the pad base Tₜ may vary from about 0.1 mm to about 3 mm. The Tₕ/Sₕ ratio may vary from about 0 to about 10. When the Tₕ/Sₕ ratio is higher than 10, the top surface of the polishing pad appears to be substantially flat. That is, the effects such as minimizing the pad deformation provided by the geometric characteristic of the segments may diminish. For example, as shown in FIG. 12(a), a very thin layer of the polishing pad 200 has been removed to result in very shallow grooves. The Tₕ/Sₕ ratio is as large as about 10. As the removed thickness of the polishing pad 200 becomes larger, the Tₕ/Sₕ ratios decreases from about 1 as shown in FIG. 12(b) to about 0.1 as shown in FIG. 12(c). If the removed thickness is about the same as the thickness of the whole polishing pad 200, that is, the cutting/machining process cut through the entire polishing pad 200, the Tₕ/Sₕ ratio becomes 0 (zero) as shown in FIG. 12(d). The deeper grooves may provide a longer lifetime of the polishing pad 200 and may create a deeper (larger) space for retaining the slurry during polishing. However, sufficient thickness of the remaining portions of the polishing pad may also be required to provide stiffness. As groove density and groove width increases, pad stiffness becomes more dependent on the thickness of the remaining portions, that is, the ungrooved portions of the polishing pad rather than the groove depth along. Therefore, to achieve a desired polishing effect, the Tₕ/Sₕ ratio has to be properly selected.

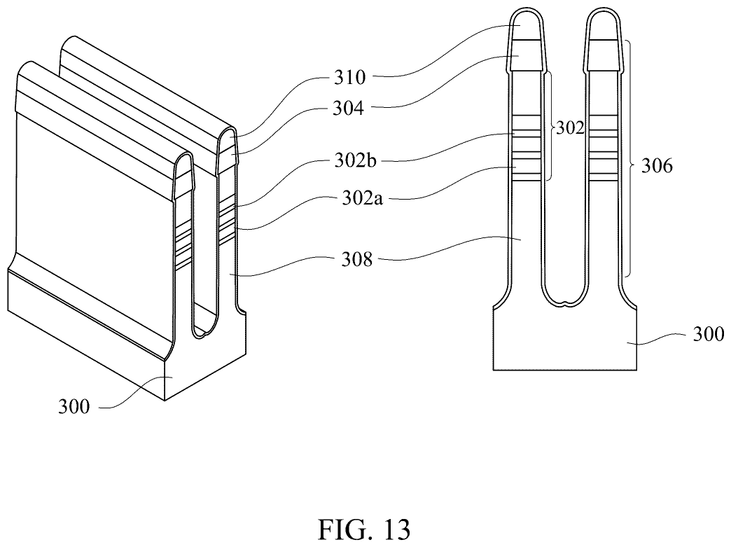

As discussed above, the CMP process with the polishing pad including discrete segments may be applied to formation of various structures in a semiconductor device. FIGS. 13-15 show the process for forming a shallow trench isolation that may be used in a FET, a gate-all-around (GAA) device, and other nano-sheet devices. Perspective views and cross-sectional views are provided in each of FIGS. 13-15. In FIG. 13, a substrate 300 is provided. According to one embodiment, the substrate 300 may be a semiconductor substrate. In some embodiments, the substrate 300 includes a single crystalline semiconductor layer on at least the surface of the substrate 300. The substrate 300 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In this embodiment, the substrate 300 is made of Si. In some embodiments, the substrate 300 is a silicon-on-insulator (SOI) substrate, which includes an insulating layer (not shown) disposed between two silicon layers. In one aspect, the insulating layer is an oxide.

One or more buffer layers (not shown) may be formed on the surface of the substrate 300. The buffer layers can serve to gradually change the lattice constant from that of the substrate to that of the source/drain (S/D) regions to be grown on the substrate 100. The buffer layers may be formed from epitaxially grown single crystalline semiconductor materials such as, but not limited to Si, Ge, germafnium tin (GeSn), SiGe, GaAs, InSb, GaP, GaSb, InAlAs, InGaAs, GaSbP, GaAsSb, GaN, GaN, and InP. In one embodiment, the substrate 200 includes SiGe buffer layers epitaxially grown on the silicon substrate 300. The germanium concentration of the SiGe buffer layers may increase from 30 atomic percent germanium for the bottom-most buffer layer to 70 atomic percent germanium for the top-most buffer layer. The substrate 300 may include various regions that have been suitably doped with impurities (e.g., p-type or n-type impurities). The dopants are, for example boron for an n-type field effect transistor FET (NFET) and phosphorus for a p-type FET (PFET).

A stack of semiconductor layers 302, including alternately formed first semiconductor layers 302a and second semiconductor layers 302b, is formed on the substrate 300. The first semiconductor layers 302a and the second semiconductor layers 302b are made of semiconductor materials having different etch selectivity and/or oxidation rates. For example, the first semiconductor layers 302a may be made of Si and the second semiconductor layers 302b may be made of SiGe. In some examples, the first semiconductor layers 302a may be made of SiGe and the second semiconductor layers 302b may be made of Si. Alternatively, in some embodiments, either of the semiconductor layers 302a and 302b may be or include other materials such as Ge, SiC, GeAs, GaP, InP, InAs, InSb, GaAsP, AlInAs, AlGaAs, InGaAs, GaInP, GaInAsP, or any combinations thereof. In the embodiment as shown in FIG. 19, the first semiconductor layers 302a are made of Si and the second semiconductor layers 302b is made of Si₁₋ₓGeₓ with x ranging between about 25% and about 50%.

The first semiconductor layers 302a or portions thereof may form nanosheet channel(s) of the semiconductor device structure in subsequent fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure may be surrounded by a gate electrode. The semiconductor device structure may include a nanosheet transistor. The nanosheet transistors may be referred to as nanowire transistors, GAA transistors, multi-bridge channel (MBC) transistors, or any transistors having the gate electrode surrounding the channels. The use of the first semiconductor layers 302a to define a channel or channels of the semiconductor device structure.

The first and second semiconductor layers 302a and 302b may be formed by any suitable deposition process, such as epitaxy. For example, epitaxial growth of the layers of the stack of semiconductor layers 302 may be performed by a molecular beam epitaxy (MBE) process, a metalorganic chemical vapor deposition (MOCVD) process, and/or other suitable epitaxial growth processes. The semiconductor layers 302a may define the channels of an FET, such as a n-type FET (NFET) or the channels of a second FET, such as a p-type FET (PFET). The thickness of the first semiconductor layers 302a is chosen based on device performance considerations. In some embodiments, the second semiconductor layers 302b may eventually be removed and serve to define spaces for a gate stack to be formed therein.

In FIG. 13, the stack of semiconductor layers 302 includes three first semiconductor layers 302a and four second semiconductor layers 302b. It is appreciated that the numbers of the first and second semiconductor layers 302a and 302b in the stack of semiconductor layers 302 may vary depending on the desired number of nanosheet channels needed for the semiconductor structure.

A hard mask 304 may be formed on the stack of semiconductor layers 302. The hard mask 304 may include an oxygen-containing layer and a nitrogen-containing layer. The oxygen-containing layer may be a pad oxide layer, such as a SiO₂ layer. The nitrogen-containing layer may be a pad nitride layer, such as Si₃N₄. The hard mask 304 may be formed by any suitable deposition process, such as chemical vapor deposition (CVD) process or plasma enhance atomic layer deposition (PEALD). The stack of semiconductor layers 302, a portion of the substrate 300, and the hard mask 304 are then patterned to form into at least two fin structures 306. Each of the fin structures 306 includes the stack includes a well portion 208 formed by one of the patterned portions of the substrate 300 and one of the stacks of the semiconductor layers 302. A liner layer 310 such as an oxide liner may be conformally formed to cover the exposed surface of the fin structures 306.

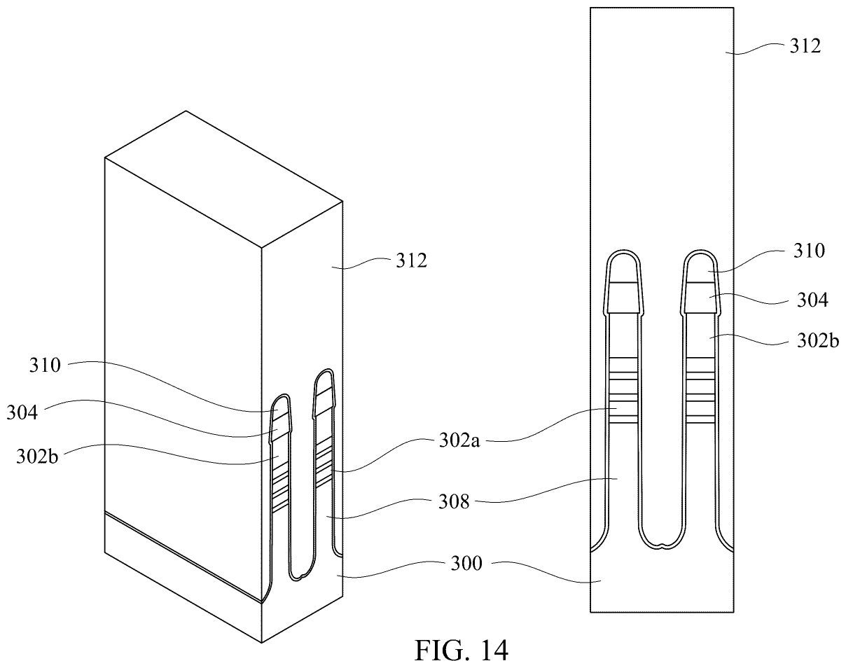

In FIG. 14, a dielectric layer 312 is formed over the semiconductor structure as shown in FIG. 13 and filling the trenches between the fin structures 306. The dielectric layer 312 may include a silicon oxide deposited by processes such as high-density plasma (HDP). The high-density plasma allows the deposition of oxide to fill small trenches without leaving voids therein. Other process such as chemical vapor deposition (CVD), plasma enhanced chemical vapor deposition (PECVD), or other similar processes may also be used for forming the oxide layer. The CMP process is then performed to remove the silicon oxide layer 312 with the hard mask layer 304 as an etch stop as the removal rate of the silicon nitride is about three times slower than the removal rate of silicon oxide. The CMP process is performed with a porous polishing pad that includes a plurality of discrete segments. Each of the segments has a maximum width S_{d} smaller than about 5 mm. In some embodiments, S_{d} may be as small as about 0.5 mm. The discrete arrangement and the sufficiently small dimension of the segments prevent the long-range deformation of the polishing pad during CMP process.

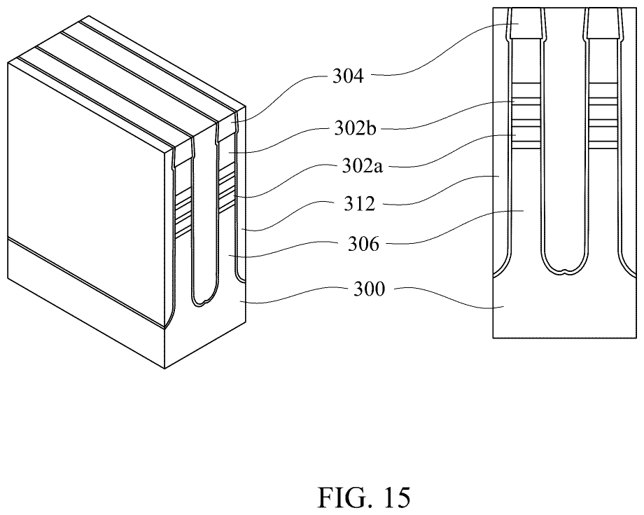

In addition to the maximum width S_{d} of the segments, the S_{d}/G_{w} ratio, the Tₜ/Sₕ ratio, hardness of the segments (or the polishing pad), the material for forming the polishing pad, the landing type, that is, the geometric shape of the surface (top surface or bottom surface of the polishing pad) to be in contact with the wafer during polishing, may be adjusted to optimize polishing effect of the oxide material. For example, grooves defined by the segments may have a width G_{w} ranging from about 0.2 mm to about 5 mm. The ratio of maximum width to groove width S_{d}/G_{w} is about 0.2 to 5 mm. The segments may have a height Sₕ ranging from about 0.1 mm to about 3 mm on a pad base with a thickness Tₜ ranging from about 0 to about 3 mm. The Tₜ/Sₕ ratio may range from about 0 to about 10. In some embodiments, each of the segments may have a top surface and a bottom surface in the shape of a circle, square, tetragon, triangle, hexagon, or other polygonal shape. The pores in the polishing pad may have a size ranging from about 5 μm to about 50 μm. A substantially flat surface of the shallow trench isolation as shown in FIG. 15 can be expected.

In addition to the formation of dielectric structure such as STI as discussed above, CMP has also been widely used to form conductive structure, for example, to planarize the metal surface and define the metal line thickness in copper (Cu) back-end-of-line (BEOL) technology. Since Cu is softer than oxide, it is more sensitive to chemical slurry; and hence results in a faster polishing rate of Cu compared to its surrounding material such as silicon oxide. Therefore, to polish Cu by CMP, the pad hardness is controlled at a lower part of the range between about 10 Shore D and about 80 Shore D, while the pad hardness selected for polishing oxide material may be selected from a higher part of the range between 10 Shore and 80 Shore D.

The formation of segments with a sufficiently small maximum width S_{d} of the polishing pad prevents lateral spread of a downward force exerted to the polishing pad during CMP process. As the long-range deformation of the polishing pad is prevented, the edge uniformity can be improved. As a result, the within-wafer (WIW) and within-zone (WIZ) uniformity can be enhanced. The wafer to wafer (WTW) improvement can also be expected. In addition, the porous structure of the segments allows the polishing pad to be properly conditioned with diamond dresser. The surface of the polishing pad can be properly refreshed to avoid the defects and stability issues caused by the flattened polishing surface. The polishing pads may be used in most technology generations, including N20, N16, N10, N7, N5, N3, N2, and beyond N2. The CMP process using the polishing pad can be applied during multiple stages, for example, front-end of the line (FEOL), back-end of the line (BEOL), middle-end of the line (MEOL), far-back-end of the line (FBEOL), and other suitable processing stages.

According to some embodiments, a chemical mechanical polishing device is provided. The chemical mechanical polishing device includes a porous polishing pad in which a plurality of pores is formed and a plurality of discrete segments at one side thereof. The segments have a maximum width S_{d} no larger than a predetermined value, for example, 5 mm, to prevent from laterally spreading a deformation caused by a downward force applied thereto. In some embodiments, the maximum width S_{d} is about 0.5 mm to about 5 mm. The polishing pad may further comprise a plurality of grooves defined by the segments. The grooves may have a width G_{w} between adjacent segments ranging from about 0.2 mm to about 5 mm in some embodiments. The ratio of S_{d}/G_{w} may range from about 0.2 to about 5. The polishing pad may further comprise a pad base on which the segments from formed. In some embodiments, the segments have a height Sₕ ranging from about 0.1 mm to about 3 mm and the pad base has a thickness Tₕ ranging from about 0 to 3 mm. The ratio of Tₕ/Sₕ is about 0 to 10. The segments may have a circular, square, rectangular, triangular, hexagonal, octagonal, or any polygonal bottom or top surface. The pores may have a size about 5 μm to about 50 μm. The polishing pad may have a hardness of about 10 Shore D to about 80 Shore D. The polishing pad may be made of polyurethane, polyimide, polyester, or polycarbonate.

According to another embodiment, a method of forming a polishing pad for a chemical mechanical polishing device. The method includes forming a continuous porous disk by mixing a pad material with a pore foaming agent and forming a plurality of segments by cutting or machining one side of the continuous porous disk. The segments are formed with a maximum width no larger than a predetermined value to prevent lateral spread of a downward force applied thereto during polishing. The method may further define a remaining portion of the continuous porous disk as a pad base. The predetermined value is 5 mm. The segments may have a maximum width of about 0.5 mm to about 5 mm. The method further defines a plurality of grooves between the segments, wherein a ratio of the maximum width S_{d} to a width of the grooves G_{w} (S_{d}/G_{w}) is about 0.2 to about 5.

In yet another embodiment, a method of forming a semiconductor device is provided. The method includes forming a material layer on a substrate and planarizing the material layer by a chemical mechanical process. The chemical mechanical process is performed using a polishing pad having a plurality of pores formed therein and a plurality of segments with a maximum width no larger than 5 mm. The method further includes forming the polishing pad with a groove design defined by the segments, and a ratio of the maximum width to a width of grooves between the segments is about 0.2 to about 5.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A chemical mechanical polishing device, comprising:
a porous polishing pad, comprising a plurality of pores formed therein and a plurality of discrete segments at one side thereof, wherein
the segments have a maximum width S_{d}, wherein the width S_{d} is equal to or less than a predetermined value to prevent from laterally spreading a deformation caused by a downward force applied thereto.

2. The device of claim 1, wherein the predetermined value is about 5 mm.

3. The device of claim 1, wherein the maximum width S_{d} is in a range between about 0.5 mm and about 5 mm.

4. The device of claim 1, the polishing pad further comprising a plurality of grooves defined by the segments.

5. The device of claim 4, wherein the grooves have a width G_{w} between adjacent segments ranging from about 0.2 mm to about 5 mm.

6. The device of claim 5, wherein a ratio of S_{d}/G_{w} is about 0.2 to about 5.

7. The device of claim 1, wherein the polishing pad further comprising a pad base on which the segments are formed.

8. The device of claim 7, wherein the segments protruding over the pad base for a height Sₕ ranging from about 0.1 mm to about 3 mm and the pad base has a thickness Tₕ ranging from about 0 to 3 mm.

9. The device of claim 8, wherein a ratio of Tₕ/Sₕ is about 0 to 10.

10. The device of claim 1, wherein the segments have a circular, square, rectangular, triangular, hexagonal, octagonal, or any polygonal bottom or top surface.

11. The device of claim 1, wherein the pores have a size about 5 μm to about 50 μm.

12. The device of claim 1, wherein the polishing pad has a hardness of about 10 Shore D to about 80 Shore D.

13. The device of claim 1, wherein the polishing pad is made of polyurethane, polyimide, polyester, or polycarbonate.

14. A method of forming a polishing pad for a chemical mechanical polishing device, comprising:
forming a continuous porous disk by mixing a pad material with a pore foaming agent; and
forming a plurality of segments by cutting or machining one side of the continuous porous disk, wherein
the segments are formed with a maximum width no larger than a predetermined value to prevent lateral spread of a downward force applied thereto during polishing.

15. The method of claim 14, further defining a remaining portion of the continuous porous disk as a pad base.

16. The method of claim 14, wherein the predetermined value is 5 mm.

17. The method of claim 14, wherein the maximum width of the plurality of segments is in a range between about 0.5 mm and about 5 mm.

18. The method of claim 14, further comprising defining a plurality of grooves between the segments, wherein a ratio of the maximum width S_{d} to a width of the grooves G_{w} (S_{d}/G_{w}) is about 0.2 to about 5.

19. A method of forming a semiconductor device, comprising:
forming a material layer on a substrate; and
planarizing the material layer by a chemical mechanical process using a polishing pad having a plurality of pores formed therein and a plurality of segments with a maximum width no larger than 5 mm.

20. The method of claim 19, further comprising forming the pad polishing with a groove design defined by the segments, a ratio of the maximum width to a width of grooves between the segments is about 0.2 to about 5.
